(19) United States
(12) Patent Application Publication
(10) Pub. No.: US 2011/0008145 A1
(43) Pub. Date: Jan. 13, 2011

(54) METHOD OF, AND APPARATUS FOR, SEPARATING WAFERS FROM A WAFER STACK

(75) Inventor: Reinhard Huber, Freudenstadt-Dietersweiler (DE)

Correspondence Address: AKERMAN SENTERFITT, P.O. BOX 3188, WEST PALM BEACH, FL, 33402-3188, US

(73) Assignee: Gebr. Schmid GmbH & Co., Freudenstadt (DE)

(21) Appl. No.: 12/814,200

(22) Filed: Jun. 11, 2010

Related U.S. Application Data
(63) Continuation of application No. PCT/EP2008/010527, filed on Dec. 11, 2008.

(30) Foreign Application Priority Data
Dec. 11, 2007 (DE) 10 2007 061 410.3

(51) Int. Cl. H01L 21/67; B65G 59/02

(52) U.S. Cl. 414/795.5; 414/801

(57) ABSTRACT

In a method of separating wafers (12) from a vertical wafer stack (16), the wafers (12) are transported away individually from above via movement means (23). The movement means (23) include circulating belts (24), with a suction surface (25) against which the uppermost wafer (12) abuts, the abutment of the wafer against the suction surface (25) being enhanced by negative pressure. To separate a plurality of wafers (12) located one upon another, the movement means (23) are subjected to at least one of the following two steps: a) water (30) is forcefully jetted against the leading edge of the uppermost wafer (12), the water being directed obliquely from beneath the latter, or b) the movement means (23) guide the wafer (12) over a stripping device (32) which butts against the underside of the moving wafer and both forces the wafer against the suction surface (25) and generates a braking action thereon. Thereafter, the wafer (12) is moved to a transporting path (35, 37) to be transported for further processing.

### FIELD OF APPLICATION AND PRIOR ART

The invention relates to a method for separating wafers from a wafer stack, in the form that they exist following the sawing of a wafer block and the release from a beam, for example of glass, as well as an apparatus suitable for performing this method.

Following the sawing of a silicon wafer block, it is necessary for separating into individual wafers to separate them from the resulting stack or the other wafers, so that they are present in single form and subsequently be further processed. Normally after the stack of wafers has been released from a beam to which the wafers or wafer block were fixed, it is placed in an upright position, so that the individual wafers are stacked on top of one another. Then the very thin and therefore very sensitive wafers are individually removed by hand and placed on a conveyor means for further conveying to a subsequent further processing station.

To carry out such work by hand is very time and cost-intensive. It also suffers from the disadvantage that it is scarcely possible to sufficiently carefully handle the very sensitive and even thinner wafers and as a result there is a considerable risk of wafer damage.

### Problem and Solution

The problem of the invention is to provide an aforementioned method and an aforementioned apparatus making it possible to obviate the problems of the prior art and in particular allow a rapid and very careful separation of the wafers from a wafer stack.

This problem is solved by a method for separating wafers from a wafer stack, said wafer stack being vertically stacked in superimposed manner and said wafers are individually conveyed away from above via movement means acting from above, wherein said movement means are constructed in revolving manner with a suction surface which is applied onto a top wafer of said wafer stack, wherein vacuum or suction is provided for intensifying an engagement of said top wafer on said suction surface or on said movement means, wherein for separating several said superimposed wafers at least one of the two following steps is performed:
a) water is jetted in intensified manner obliquely from below said top wafer against a front edge of said wafer,
b) b) said movement means guide said top wafer over a stripping apparatus, said stripping apparatus engaging from below on an underside of said wafer and pressing said wafer against said movement means or said suction surface and also producing a braking action thereon,
   wherein subsequently said wafer is brought on to a conveyor means for conveying away. This problem is also solved by an apparatus for performing this method, wherein there are provided revolving movement means with a suction surface on an underside, water jet nozzles and a stripping apparatus between said water jet nozzles and a following conveyor means, said conveyor means being constructed for application and conveying away of said wafer removed from said wafer stack. Advantageous and preferred developments of the invention form the subject matter of the further claims and are explained in greater detail hereinafter. Some of the features of the apparatus are not explained separately and instead only in conjunction with the method so as to avoid unnecessary repetition. By explicit reference, the wording of the claims is made into part of the content of the description.

According to the invention, movement or moving means act from above on the wafer stack or on the top wafer and are constructed so as to rotate or revolve and have a suction surface, which is directed downwards. On said suction surface is placed the top wafer, the engagement of the wafer on the suction surface or as a result on the movement means can be further reinforced by vacuum or suction. Thus, by means of the movement means and suction surface via static friction on the one hand and vacuum on the other, an adequate amount of force can be exerted on the wafer, so that despite the adhesive action it can be released from the wafer stack and conveyed on. This adhesive action is brought about by adhesion due to the water on the wafer stack and between the individual wafers, particularly through the hydrogen bridges formed there. To assist the separation of several superimposed wafers, which are so-to-speak suspended on the movement means or the top wafer, at least one of the two subsequently described steps a) or b) is performed and advantageously both of these. In step a) water is pumped or jetted against the front edge of the top wafer in oblique manner from below. For this purpose advantageously correspondingly constructed water nozzles are provided and there is at least one, but with particular advantage two or more. As a result of their action, the water jet, which can even be produced immersed in water where it can have an effect, the front edges of several mutually adhering wafers are separated and can be spread fanwise.

In step b) the wafers are guided by the movement means over a stripping apparatus, which is constructed in such a way that it is engaged from below on the underside of the moving wafer or the several gripped wafers. This stripping apparatus presses the wafer or wafers onto the movement means or suction surface. Whilst the top side of the top wafer is moved away from the water stack by the movement means, it exerts a braking action on the underside of said wafer. Said stripping apparatus consequently also serves to further separate several wafers moved away at once from the wafer stack. If there is only one wafer on the movement means, the braking action of the stripping apparatus is no longer adequate to hold the same or detach it from the movement means. Thus, in much the same way as the aforementioned jetting with water, the stripping apparatus serves to separate several gripped wafers. After carrying out at least one of the two above-described steps, the wafer is brought from the movement means onto a conveyor means and is then conveyed away.

It is admittedly fundamentally possible to individually perform each of the two steps a) or b). However, advantageously both steps are performed together or successively. This is dependent on the sequence or the construction in such a way that following the gripping of the top wafer by the movement means, there is firstly a jetting with water and then the stripping apparatus is provided behind or downstream the same.

In a development of the invention the movement means can be constructed in such a way that they have a movable revolving belt. It advantageously runs over a greater length and with particular advantage to a following conveyor means, roughly parallel to the top side of the wafer stack. The aforementioned suction surface is then located on the movable belt or is formed by the latter, so that when the top wafer approaches the movement means the latter engage with the suction surface in as large-area manner as possible on the top side of the top wafer. In an alternative development of the invention a movement means can have a wheel-like construction or is provided with at least one wheel or roll. Advantageously several such wheels or rolls are successively provided in order to form an elongated movement means with several contact points between the movement means and the wafer top side, so that an adequate force is exerted on the top wafer, so that it is released from the wafer stack and can be conveyed away.

In a development of the invention at least two similar movement means are provided and are arranged in juxtaposed or parallel manner. They are advantageously spaced from one another or there are at least two similar movement means, so that between the same the indicated spacing or a corresponding gap is provided. Whilst the movement means advantageously have closed surfaces, particularly in order to form the aforementioned suction surfaces, in the vicinity of the indicated spacing a perforated surface is formed between them which is in particular rigid and has openings or holes. On said perforated surface or at the openings a suction action is produced from above, for example as a simple suction effect with a corresponding vacuum. As a result, the top side of the top wafer is drawn upwards from the wafer stack and pressed against the underside of the movement means or against the suction surface formed by the latter, so as to permit satisfactory moving on. To this end, the perforated surface is advantageously positioned somewhat above the suction surfaces, because said perforated surface is advantageously rigid or is constructed in planar manner as a plate. Alternatively the movement means could have openings, for example in the form of a perforated belt and then from above a vacuum is produced by suction action in order to have a suction effect on the top side of the wafer. It is generally possible to immerse the wafer stack during separation or gripping with the movement means in water, so that the wafers can be more easily separated.

In a further development of the invention the water jet can be ventilated or aerated for assisting the separation of the wafers from the wafer stack or can contain air or gas bubbles. Said ventilating effect can be produced by introducing air or gas into the water jet or into a nozzle for the same. This is for example possible in a similar manner to the ventilation or aeration of the outlet of a water tap or faucet using ventilating apparatus, such as are for example produced in mesh or net form by the Neoperl company. Such a ventilated water jet has the advantage that it is not only the water pressure alone which may spread in fanlike manner the front edges of the top wafers of the wafer stack, but instead air bubbles can pass between the individual wafers and as a result the adhesive action can be eliminated. Another advantageous effect of this water jet is that, in the same way as is described hereinafter for the stripping apparatus, it can also serve to press a wafer against the suction surface.

It is considered advantageous if the water jet has an angle to the horizontal between 20° and 70°. With particular advantage this angle is between 35° and 60°.

One possibility for constructing a stripping apparatus is to have an upwardly directed brush under the conveying path of the wafer fitted to the movement means following the wafer stack. The brushes must be made from a sufficiently soft material, so that they do not damage or scratch the sensitive wafers. However, they must also be able to exert a certain braking action if one or more wafers are led past the movement means thereon. In particular, if in combination with the above-described step a) of jetting with water, the movement means grip several wafers or suspension occurs on the top, gripped wafer as a result of the water jet, a certain displacement of the wafer can have taken place counter to the conveying direction. The stripping apparatus can increase this, which simplifies separation.

As an alternative to a brush, a stripping apparatus can be constructed in revolving or rotary manner, for example once again as a roll or belt. It can engage on the underside of one or more wafers engaging on the movement means and can decelerate the bottom wafer or draw away somewhat from the upper wafer.

A conveyor means for conveying on the wafers is advantageously constructed as a roller conveyor. However, it can also have belts, straps or the like. Advantageously for depositing and conveying on the wafers, behind the stripping apparatus the conveyor means is advantageously constructed in such a way that it serves to further separate still at least partly superimposed wafers. For this purpose it can have several sections arranged successively in the conveying direction and which in each case have a rising speed. As according to step a) or b) as a result of the upstream water jet nozzle and the stripping apparatus a group of for example three or four wafers which are still partly adhering to one another is displaced in such a way that the top wafer projects with its front edge well above the lower wafer, it is firstly gripped by the in each case following conveyor means section. If said section is faster than the preceding section and a speed difference exists, it is additionally drawn away from the other wafers, either completely or at least by a certain amount. Through the provision of several such sections, which in each case have faster speeds, ultimately there is an even more reliable separation of several wafers. It is advantageous for this purpose, if the surface or top side of the conveyor means is constructed in highly adhesive manner in conjunction with the undersides of the wafers.

A further improvement to the removal of individual wafers from the wafer stack can be brought about in that the wafer stack is uniformly moved up and down or with an oscillating movement. This can take place with a recurrence period of a few seconds, for example three to five seconds. A swing or amplitude should be max. 10 mm, preferably approximately 5 mm. If the cycle time for removing a wafer from the wafer stack is chosen similar to the aforementioned recurrence period, namely a few seconds, it is possible to ensure that on each occasion when the wafer stack has reached its apex, the top wafer is pressed somewhat against the movement means or the suction surface which then does not have to move downwards. The gripping or adhesive action should take place very rapidly due to a continuous suction. This results in the lateral movement of conveying away and a moving down of the wafer stack, so that the probability is very high that the movement means grips only one or at the most a few wafers or only a few further wafers hang down from the top, gripped wafer. In certain circumstances, there can be slight vibrating movements on the wafer stack in order to aid the mutual release of the wafers.

The construction of the inventive apparatus for performing the described method can be gathered from the above method description with the in each case individual functional units for steps a) and b). Reference is made to the description relative to the drawings regarding the specific construction possibilities.

These and further features can be gathered from the claims, description and drawings, and the individual features, both singly and in the form of subcombinations, can be implemented in an embodiment of the invention and in other fields and can represent advantageous, independently protectable constructions for which protection is claimed here. The subdivision of the application into individual sections and the subheadings in no way restrict the general validity of the statements made thereunder.

### BRIEF DESCRIPTION OF THE DRAWINGS

Embodiments of the invention are illustrated in the attached diagrammatic drawings and described in detail hereinafter. The drawings show:

FIG. 1 a side view of a diagrammatic functional construction of a apparatus to explain the method according to the invention;

FIG. 2 a plan view of the movement means in the form of two parallel belts with a perforated surface between them; and

FIG. 3 an alternative of the movement means of FIG. 2 with a single belt having a perforated surface.

### DETAILED DESCRIPTION OF THE EMBODIMENTS

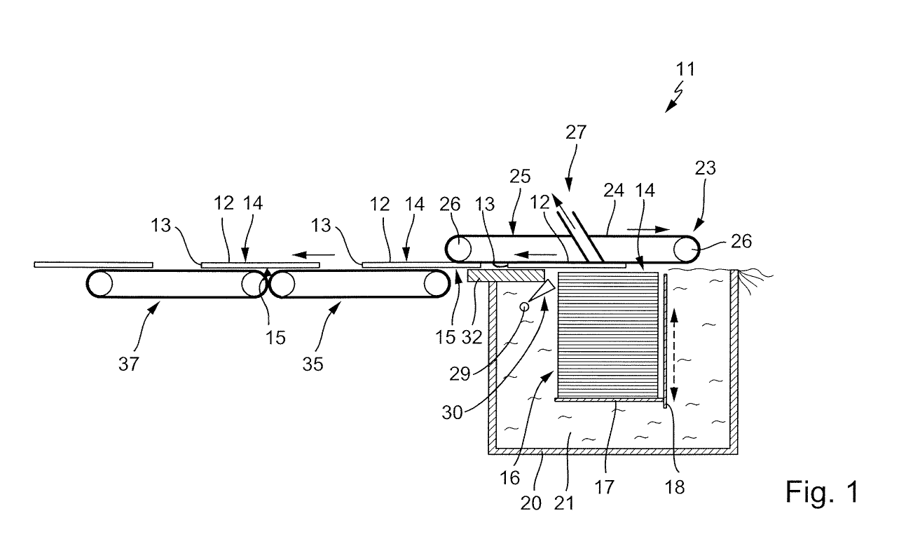

FIG. 1 shows an apparatus 11 according to the invention enabling individual wafers 12 to be removed from a wafer stack 16 and moved away for conveyance to further processing. The wafers 12 are shown with their upwardly directed top side 14 and a leftward-directed front edge 13. They are stacked on wafer stack 16, which is located on or in a magazine 17, which is in turn fitted on or in a lifting apparatus 18. Magazine 17 with wafer stack 16 is brought by not shown means into lifting apparatus 18, which is in turn placed in a water tank 20 filled with water 21. It is clear that the top side 14 of the top wafer 12 of wafer stack 16 is roughly level or somewhat below the edges of water tank 20. Thus, water tank 20 can have a certain overflow ensuring that for example following refilling with water 21 from below, the individual wafers 12 or wafer stack 16 floats or is fanned out upwards and ensures a certain water circulation. In place of normal mains water 21 in water tank 20, the latter can also contain DI water or cleaning solution.

The broken line arrow alongside lifting apparatus 18 makes it clear that the latter moves up and down with the indicated movement for example in an interval or with a movement duration of a few seconds and a movement height of max. 10 mm.

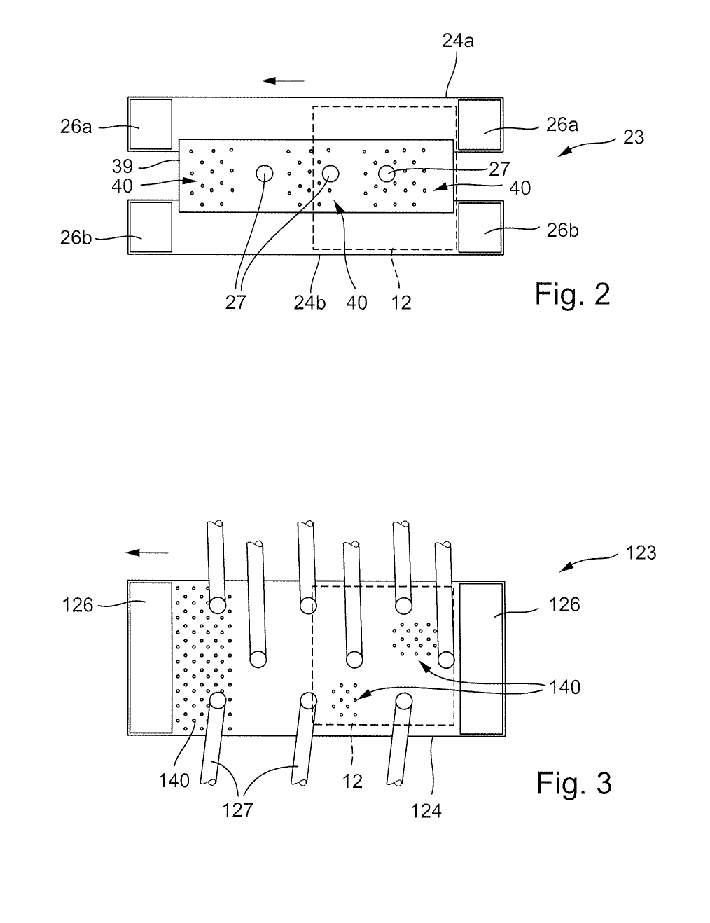

Above the wafer stack 16 are provided movement means 23, which have a clockwise revolving belt 24 or two juxtaposed belts. Reference should be made to FIG. 2 for further details. One surface 25 of belt 24 forms the aforementioned suction surface 25. By means of a suction apparatus 27 a vacuum is applied in such a way that the top side 14 of the top wafer 12 of wafer stack 16 is pressed against belt 24 or its suction surface 25 and is then grasped by the latter and moved to the left away from wafer stack 16.

Somewhat to the left alongside wafer stack 16 is shown a water nozzle 29, whose jetting direction is at an angle of approximately 45° to the horizontal and is directed against the front edge 13 of the top wafer 12 of wafer stack 16. As stated hereinbefore, a water jet 30 produced by water nozzle 29 can be ventilated or aerated by not shown ventilating or aerating means. Even if the water jet 30 is produced quasi within the water 21 of water tank 20, a jetting action can still be obtained and this serves to fan out the front edges or the wafer 12 at the top of water stack 16, particularly for the release of preferably a single wafer 12 or at the most a few wafers 12 from the wafer stack 16 using movement means 23. Directly following the water jet 30 as one of the aforementioned separation means, the movement means 23 lead the single or few wafers 12 over an aforementioned stripping apparatus for separation purposes and which is constructed as a brush 32. It advantageously extends over the entire width of a wafer 12 or the wafer stack 16 and has upwardly directed bristles, which can optionally also be directed somewhat against the conveying direction of wafers 12. Due to the fact that the underside 15 of a wafer 12, which together with the other wafers 12 has been released as a small stack from the wafer stack 16 by the movement means 23, engages on the brush, it is decelerated by the latter compared with the other wafers or at least the top wafer 12, which engages directly on the suction surface 25. As a result of the length of brush 32 in the movement direction, which is roughly of the same order of magnitude as the length of a wafer 12, several still mutually adhering wafers 12 can be separated or at least so mutually displaced that their front edges 13 have a certain mutual spacing, for example of several centimetres.

The suction action of the suction apparatus 27 or further, not shown suction apparatus, may be provided also above the brush 32. Thus, wafers 12 decelerated or released by movement means 23 from brush 32 may then again be gripped by the suction surface 25 and conveyed on to the left.

It is also clear that the movement means 23 extend beyond brush 32. Then, with a certain spacing from brush 32, a first conveyor belt 35 is provided, followed by a second conveyor belt 37, etc. The first conveyor belt 35 has a certain spacing both from the movement means 23 and the brush 32. It is clear that at least following brush 32 for the case that several wafers 12 adhere to suction surface 25, the front edges 13 thereof are displaced to the right. Consequently this means that firstly the wafer 12 adhering directly to suction surface 25 reaches or engages on the first conveyor belt 35. Said first conveyor belt 35 runs with a much higher speed than the movement means 23, for example a double speed. Thus, whereas the front edge 13 of top wafer 12 is gripped by the first conveyor belt 35, the remaining wafers are still decelerated by the brush 32. Thus, also as a result of this the top wafer 12 is drawn off as a single wafer and is placed individually on the first conveyor belt 35.

The second conveyor belts 37 directly following the conveyor belt 35 once again runs at a much higher speed, for example at least twice the speed. As a result of the speed difference the effect is much the same as for brush 32, namely that also here the speed difference serves to firstly grip the wafer 12 extending furthest to the left and draw it away from the other wafers, whose underside 15 still rests on the first conveyor belt 35.

At the latest following the second conveyor belt 37 all the wafers are separated. Any differing mutual spacing, in the way in which they rest on the conveyor means, can be compensated by known mechanisms.

The wafers 12 typically have a thickness of somewhat above 200 μm and edge lengths between 100 and 200 mm in the case of a rectangular or roughly square format.

FIG. 2 is a sectional plan view of a median plane of a section through the movement means 23 of FIG. 1. The movement means 23 have two similar belts 24a, 24b, which are juxtaposed with a certain spacing, which is smaller than their width and are driven by wheels 26a and 26b. The outsides or surfaces of the belts 24a and 24b form the aforementioned suction surface 25. This does not necessarily mean that said surface 25 exerts a suction action, but instead that the top side 14 of wafer 12 is placed against the same by suction action.

Over the gap between the belts 24a and 24b there is a perforated plate 39 with a plurality of small holes 40, for example having a diameter of a few millimetres. Above the perforated plate 39 there are three suction apparatus 27, for example in the form of tubes. They have a vacuum-like suction action and draw water 21 from the water tank 20. Simultaneously through the holes 40 they exert a suction action on the top side 14 of the top wafer 12 of wafer stack 16. As a result, there is an upward movement and remains applied following the engagement on the suction surfaces 25 of the belts 24a and 24b, whilst it is still being drawn upwards by the suction action. As the wafer 12 should not engage directly on the perforated plate 39 and instead only engage on belts 24a and 24b, it is simultaneously moved to the left in FIGS. 1 and 2 with the continuous movement thereof and consequently away from the wafer stack 16. Wafer 12 is here shown in broken line form in a position such as it occupies on wafer stack 16.

FIG. 2 makes it clear that it is advantageous, although not mandatory, to provide several suction apparatus 27 so as to ensure a suction action over a considerable length of the movement means 23 and perforated plate 39 in the conveying direction. This makes it possible to ensure that a wafer 12 is always sucked against the suction surface 25 of belts 24a and 24b.

In a further development of the invention more than two juxtaposed belts 24 can be provided and then they correspondingly have several perforated plates 39 between them. As stated, wheels could be used in place of belts 24. However, as they are only able with difficulty to apply the necessary static friction for conveying the wafers 12 away from wafer stack 16, a clear preference is given to belts.

An alternative of the movement means is shown in FIG. 3 with movement means 123 having a single belt 124. Said belt 124 runs on two wheels 126, much like the belts in FIG. 2. However, as here there is no spacing between the belts and consequently no perforated plate can be used as in FIG. 2, the belt 124 is itself perforated and has holes 140, for example similar to those of the perforated plate 39 in FIG. 2. Above the lower belt 124, which on its outside forms the suction surface 125, there are several suction apparatus 127 with a given distribution. With respect to their suction action and advantageously with respect to their direct constructional arrangement, they should extend over the width of belt 124 or a wafer 12 shown in broken line form, as well as over a certain area of the length of belt 124. Whereas the suction apparatus 27 having a tubular shape in FIG. 2 can be continued directly upwards, in FIG. 3 it must be displaced to the side, virtually from the revolving loop of belt 124.

The arrangement according to FIG. 3 has the advantage that it is more simple in construction than in the case of perforated plate 39. Moreover, the suction using perforated belt 124 can be carried out directly on the suction surface 125 of belt 124, so that the top side 14 of wafer 12 precisely adheres to the surface, which laterally conveys them away and onto which they are sucked. The intensity of the suction action can generally be adjusted via the suction apparatus on the one hand and via the size of the holes on the other. This can optionally also take place via the height of the perforated plate 39 above the underside of belts 24 in accordance with FIG. 2.

1. A method for separating wafers from a wafer stack, said wafer stack being vertically stacked in superimposed manner and said wafers are individually conveyed away from above via movement means acting from above, wherein said movement means are constructed in revolving manner with a suction surface which is applied onto a top wafer of said wafer stack, wherein vacuum or suction is provided for intensifying an engagement of said top wafer on said suction surface or on said movement means, wherein for separating several said superimposed wafers at least one of the two following steps is performed:
a) water is jetted in intensified manner obliquely from below said top wafer against a front edge of said wafer,
b) said movement means guide said top wafer over a stripping apparatus, said stripping apparatus engaging from below on an underside of said wafer and pressing said wafer against said movement means or said suction surface and also producing a braking action thereon,
wherein subsequently said wafer is brought on to a conveyor means for conveying away.

2. The method according to claim 1, wherein said movement means have a movable belt, which runs over a considerable length up to a following conveyor means and roughly parallel to a top side of said wafer stack.

3. The method according to claim 1, wherein at least two similar said movement means are juxtaposed or in parallel and have a mutual spacing, said movement means having closed surfaces, wherein in a region of said mutual spacing between said movement means a perforated surface is provided with openings, wherein on said openings a suction action is produced from above for sucking and pressing a top side of said top wafer of said wafer stack against an underside of said movement means.

4. The method according to claim 1, wherein said water jet is ventilated and contains air or gas bubbles, being produced by introducing air or gas into a nozzle for said water jet.

5. The method according to claim 1, wherein said water jet has an angle to the horizontal between 20° and 70°.

6. The method according to claim 1, wherein said stripping apparatus has an upwardly directed brush.

7. The method according to claim 6, wherein said brush is at least as wide and/or as long as one of said wafers.

8. The method according to claim 1, wherein said stripping apparatus revolves or rotates in the form of a roller or a belt, and engages on an underside of said wafer engaging on said movement means for braking and separating a lower wafer adhering to said upper wafer engaging on said movement means.

9. The method according to claim 1, wherein said conveyor means is constructed for depositing wafers behind said stripping apparatus for further separation from still superimposed wafers as a result of a rising speed of numerous individual conveyor means sections successively positioned in said conveying direction.

10. The method according to claim 9, wherein said conveyor means are designed as a roller conveyor or as a conveyor belt.

11. The method according to claim 1, wherein said wafer stack is moved up and down with a kind of oscillating movement.

12. The method according to claim 11, wherein said wafer stack is moved up and down with a time interval of about 5 seconds, and with a movement height of max. 10 mm.

13. An apparatus for performing the method according to claim 1, wherein there are provided revolving movement means with a suction surface on an underside, water jet nozzles and a stripping apparatus between said water jet nozzles and a following conveyor means, said conveyor means being constructed for application and conveying away of said wafer removed from said wafer stack.
